(19) United States
(12) Patent Application Publication
(10) Pub. No.: US 2017/0025622 A1
(43) Pub. Date: Jan. 26, 2017

(54) ULTRASENSITIVE SOLUTION-PROCESSED PEROVSKITE HYBRID PHOTODETECTORS

(71) Applicants: Xiong Gong, Hudson, OH (US); Kai Wang, Akron, OH (US); Chang Liu, Akron, OH (US)

(72) Inventors: Xiong Gong, Hudson, OH (US); Kai Wang, Akron, OH (US); Chang Liu, Akron, OH (US)

(73) Assignee: The University of Akron, Akron, OH (US)

(21) Appl. No.: 15/124,464

(22) PCT Filed: Mar. 12, 2015
(86) PCT No.: PCT/US15/20286

§ 371 Date: Sep. 8, 2016

Related U.S. Application Data
(60) Provisional application No. 61/951,567, filed on Mar. 12, 2014.

(51) Int. Cl. H01L 51/00; H01L 31/0256

(52) U.S. Cl. CPC H01L 51/0077; H01L 31/0256; H01L 51/0036; H01L 51/0047; H01L 51/0037; H01L 51/4226

(57) ABSTRACT

A photodetector includes an active layer formed of an inorganic/organic hybrid perovskite material, such as organometal halide perovskites. The perovskite hybrid photodetector provides low dark-current densities and high external-quantum efficiencies, resulting in a photodetector with enhanced photoresponsivity and detectivity. Advantageously, the perovskite hybrid photodetector may be prepared by solution processing, and is compatible with large-scale manufacturing techniques.

### CROSS-REFERENCE TO RELATED APPLICATION

This application claims the benefit of U.S. Provisional Application No. 61/951,567 filed Mar. 12, 2014, the contents of which are incorporated herein by reference.

### TECHNICAL FIELD

The present invention relates generally to photodetector devices. Particularly, the present invention is directed to photodetectors that include a perovskite active layer. More particularly, the present invention relates to photodetectors that include a perovskite hybrid active layer that is formed through solution processing.

### BACKGROUND OF THE INVENTION

Photodetectors or PDs, such as photodiodes and solar cells, are among the most ubiquitous types of technology in use today. Their application includes, among others, chemical/biological sensing, environmental monitoring, daytime/nighttime surveillance, as well as use in remote-control devices, such as television remotes for example. During the evolution of photodetectors, various types of semiconductor materials have been utilized in their design, including ZnO, Si, InGaAs, colloidal quantum dots, graphene, carbon nanotubes and conjugated polymers. Furthermore, it is desirable that the semiconductor materials used in fabricating PDs possess a high-absorption extinction coefficient, which ensures that sufficient light is able to be absorbed by the active layer of the device. This feature is important to ensure that a large charge carrier mobility is provided by the photodetector, so that high photocurrent can be generated, and to ensure that the photodetector is fabricated with a low density of structural defects, so that the dark current density is sufficiently diminished. Given the operating properties desired by photodetector designers, a hybrid organometal halide perovskite material, or perovskite material, has been considered as a promising candidate for use in photodetectors due to its properties.

Perovskite materials are direct bandgap semiconductors, which allow them to possess a high absorption extinction coefficient within the range of visible light to near infrared light. Moreover, ambipolar transport characteristics of perovskite materials enable both holes and electrons to be transported simultaneously in perovskite-based electronic devices. In addition, the long charge carrier diffusion length of perovskite materials (˜1 μm in CH₃NH₃PbI₃₋ₓClₓ, ˜100 nm in CH₃NH₃PbI₃) results in a low defect density in a perovskite thin film that is formed therefrom, which would be desirable in the fabrication of photodetectors.

Due to the desirable features of perovskite materials, perovskite-based photodetectors have been investigated. However, such efforts have failed to realize a perovskite-based photodetector that has sufficient daytime/nighttime surveillance sensitivity and chemical biological detection sensitivity. In addition, current perovskite-based photodetectors fail to achieve the desired operating features of low-power consumption and high-speed operation. In addition, perovskite PDs of existing designs suffer from decreased performance due to various reasons, including the degradation of the various layers of the detector resulting various from internal and external reactions. Thus, such existing photodetector designs are inherently flawed, giving poor long-term stability. In addition, the availability of low-work-function metal inks, such as aluminum (Al) metal inks, which are needed to manufacture electrodes of PDs based on conventional PSC designs is limited. Thus, the compatibility of such photodetector designs with continuous, low-cost roll-to-roll manufacturing technology, which requires depositing a large-area Al electrode, also remains problematic.

In addition, because conventional photodetectors are formed of inorganic materials, they require high-temperature processing, and require that the active layer be formed from an expensive metal element, thus making the photodetector a costly device.

Therefore, there is a need for an organometal halide perovskite hybrid photodetector that is formed by solution processing. There is also a need for a perovskite photodetector that can be fabricated using large-scale manufacturing techniques, such as roll-to-roll manufacturing techniques. In addition, there is a need for a perovskite (inorganic/organic) hybrid photodetector that provides enhanced photoresponsivity and detectivity over that of conventional photodetector designs, such as inorganic photodetectors. In addition, there is a need for a perovskite hybrid photodetector that eliminates the use of PEDOT:PSS and replaces a low work-function metal aluminum (Al) electrode with a high work-function metal silver (Ag) electrode to allow the photodetector to have enhanced stability.

### SUMMARY OF THE INVENTION

In one aspect of the present invention, a photodetector comprises a first electrode; an electron-extraction layer disposed on the first electrode; a perovskite active layer disposed on the electron-extraction layer; a hole-extraction layer disposed on the perovskite active layer; and a second electrode; wherein at least one of the first or second electrodes is at least partially transparent to light.

In another aspect of the present invention, a method of preparing a photodetector comprises providing a first electrode that is at least partially transparent to light; disposing an electron-extraction layer on the first electrode; disposing a perovskite light absorbing layer on the electron-extraction layer; disposing a hole-extraction layer on the perovskite light-absorbing layer; and disposing a second electrode on the hole-extraction layer.

In yet another aspect of the present invention, a method of preparing a photodetector comprises providing a first electrode that is at least partially transparent to light; disposing a hole-extraction layer on the first electrode; disposing a perovskite light absorbing layer on the hole-extraction layer; disposing an electron-extraction layered on the perovskite light absorbing layer; and disposing a second electrode on the electron-extraction layer.

### BRIEF DESCRIPTION OF THE DRAWINGS

FIG. 1 is a schematic diagram showing a device structure of one or more embodiments of a hybrid perovskite photodetector in accordance with the concepts of the present invention;

FIG. 2A is a schematic diagram showing a device structure of one or more alternate embodiments of a hybrid perovskite photodetector in accordance with the concepts of the present invention;

FIG. 2B is a graph showing the LUMO (lowest unoccupied molecular orbital) and HOMO (highest occupied molecular orbital) energy levels of TiO₂, PC₆₁BM, CH₃NH₃PbI₃, P3HT (poly(3-hexylthiophene-2,5-diyl), MoO₃ and work functions of ITO and Ag of the photodetector of FIG. 2A;

FIG. 3A is a chart showing the J-V characteristics of the hybrid perovskite photodetector of FIG. 2A under dark and under monochromatic illumination at the wavelength of 500 nm with a light intensity of 0.53 mW/cm², whereby the photodetector of FIG. 2A is structurally configured as: ITO/TiO₂/CH₃NH₃PbI₃/P3HT/MoO₃/Ag (PD represented with TiO₂), and structurally configured as: ITO/TiO₂/PC₆₁BM/CH₃NH₃PbI₃/P3HT/MoO₃/Ag (PD represented with TiO₂/PC₆₁BM);

FIG. 3B is a graph showing the external quantum efficiency (EQE) spectra of hybrid perovskite photodetector of FIG. 2A, whereby the structures of the photodetectors are configured as: ITO/TiO₂/CH₃NH₃PbI₃/P3HT/MoO₃/Ag (PD represented as TiO₂), and configured as: ITO/TiO₂/PC₆₁BM/CH₃NH₃PbI₃/P3HT/MoO₃/Ag (PD represented with TiO₂/PC₆₁BM);

FIG. 4A is a graph showing detectivities vs. wavelength of the hybrid perovskite photodetector of FIG. 2A, whereby the structures of the photodetector are configured as: ITO/TiO₂/CH₃NH₃PbI₃/P3HT/MoO₃/Ag (PD represented with TiO₂), and configured as: ITO/TiO₂/PC₆₁BM/CH₃NH₃PbI₃/P3HT/MoO₃/Ag (PD represented with TiO₂/PC₆₁BM);

FIG. 4B is a graph of the linear dynamic range of the photodetector of FIG. 2A with TiO₂/PC₆₁BM;

FIG. 5A is an atomic force microscope (AFM) height image of a TiO₂ thin film utilized by the photodetector of FIG. 2A in accordance with the concepts of the present invention;

FIG. 5B is an atomic force microscope (AFM) height image of a TiO₂/PC₆₁BM thin film in accordance with the concepts of the present invention;

FIG. 5C is an atomic force microscope (AFM) phase image of a TiO₂ thin film in accordance with the concepts of the present invention;

FIG. 5D is an atomic force microscope phase (AFM) image of a TiO₂/PC₆₁BM thin film in accordance with the concepts of the present invention;

FIG. 6 is a graph of the photoluminescence spectra of TiO₂/CH₃NH₃PbI₃ and TiO₂/PC₆₁BM/CH₃NH₃PbI₃ thin films used by the photodetector of FIG. 2A in accordance with the concepts of the present invention;

FIG. 7 is a graph showing nyquist plots at V≈V_{OC} for the hybrid perovskite photodetector of FIG. 2A, whereby the photodetector is structurally configured as: ITO/TiO₂/CH₃NH₃PbI₃/P3HT/MoO₃/Al (PD represented with TiO₂), and structurally configured as: ITO/TiO₂/PC₆₁BM/CH₃NH₃PbI₃/P3HT/MoO₃/Al (PDs with TiO₂/PC₆₁BM);

FIG. 8 is a graph of the normalized UV (ultra violet) absorption of perovskite (CH₃NH₃PbI₃₋ₓClₓ) utilized by the photodetectors of the present invention;

FIG. 9A is a schematic diagram showing the structure of another exemplary perovskite hybrid photodetector in accordance with the concepts of the present invention;

FIG. 9B is a chart showing the energy level alignment of the structural layers of the perovskite hybrid photodetector of FIG. 9A;

FIG. 10 is a graph showing the J-V characteristics of the perovskite hybrid photodetector of FIG. 9A measured under dark conditions and under illuminated conditions; and

FIG. 11 is a graph showing the EQE spectra of the perovskite hybrid photodetector of FIG. 9A measured under short-circuit condition using lock-in amplifier technique.

### DETAILED DESCRIPTION OF THE INVENTION

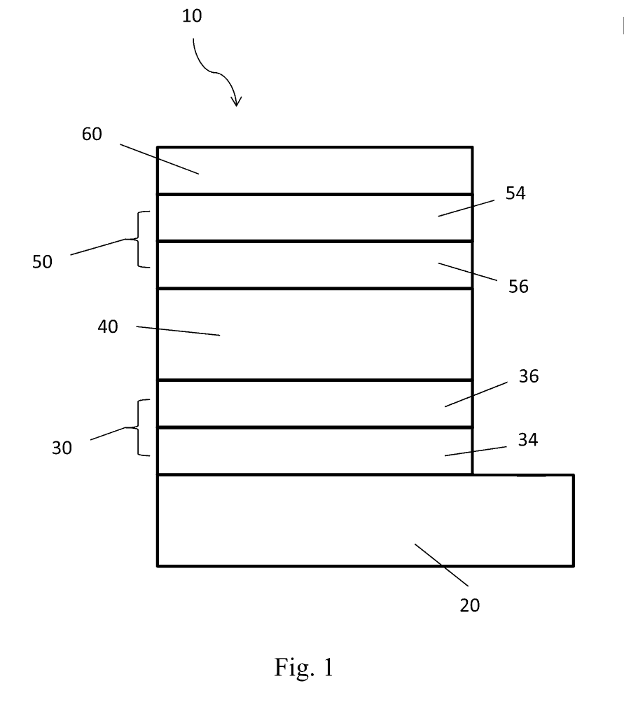

A solution-processed perovskite hybrid photodetector, or PD, is generally referred to by the numeral 10, as shown in FIG. 1 of the drawings. It should be appreciated that the terms “photodetector”, “PD”, and “pero-PD”, as used herein, are defined as any electronic light-detecting, light-sensing, or light-converting device, including, but not limited to, photodiodes and solar cells (i.e. photovoltaic devices).

Specifically, the perovskite hybrid photodetector 10 comprises a laminated or layered structure that is formed in a manner to be discussed. As such, the photodetector 10 includes an electrically-conductive electrode 20. In one or more embodiments of the photodetector 10, such as in an inverted design, the electrode 20 may be a transparent or partially-transparent electrode. In other embodiments of the photodetector 10, such as in a non-inverted configuration, the first electrode 20 may be a formed of high work-function metal. High work-function metals suitable for use in electrode 20 include, but are not limited to, silver, aluminum and gold. Positioned adjacent to the electrode 20 is an electron-extraction layer (EEL) 30. In one or more embodiments, the electron-extraction layer 30 may include an electron-extraction component layer 34 and a passivating component layer 36. In other embodiments, the electron-extraction layer 30 includes an electron-extraction component layer 34 without the passivating component layer 36.

Positioned adjacent to the electron-extraction layer 30 is a light-absorbing layer (i.e. active layer) 40, which is formed of perovskite. Positioned adjacent to the perovskite active layer 40 is a hole-extraction layer (HEL) 50. In one or more embodiments, the hole-extraction layer 50 may include one or more layers that are capable of facilitating the extraction of holes from the photodetector 10. In one or more embodiments, the hole-extraction layer 50 comprises a plurality of sub-layers, including a hole-extraction sub-layer 54 and a hole-extraction sub-layer 56. Positioned adjacent to the hole-extraction layer 50 is an electrically-conductive electrode 60. In one or more embodiments, where the photodetector 10 has an inverted configuration, the electrode 60 may be formed of a high work-function metal. High work-function metals suitable for use as electrode 60 include, but are not limited to, silver, aluminum and gold. In other embodiments, where the photodetector 10 has a non-inverted configuration, the electrode 60 may also comprise a transparent or partially-transparent electrode.

As previously discussed, the photodetector 10 includes both a transparent or partially-transparent electrode and an electrode formed from a high work-function metal. That is, one of the electrodes 20 and 60 is formed so as to be transparent or partially transparent, and positioned so that light is able to enter the photodetector 10. For example, in one or more embodiments, where the where the photodetector 10 has an inverted design, the electrode 20 may be a transparent or partially-transparent electrode, and light will enter the photodetector 10 through electrode 20. In other embodiments, where the photodetector 10 has a non-inverted design, the electrode 60 may be a transparent or partially-transparent electrode, and light will enter the photodetector 10 through electrode 60. Suitable transparent or partially-transparent materials for use as the electrodes 20,60 include those materials that are conductive and transparent to at least one wavelength of light. An example of a conductive material suitable for use as electrodes includes indium tin oxide (ITO). In certain embodiments, the conductive electrode 20,60 may be formed as a thin film that is applied to a substrate, such as glass or polyethylene terephthalate.

### Electron-Extraction Layer

The electron-extraction layer (EEL) 30 is a layer that is configured for capturing an electron generated in the perovskite light-absorbing layer 40 and transferring it to electrode 20. Exemplary materials for preparing the electron-extraction layer 30 include, but are not limited to, TiO₂ and phenyl-C61-butyric acid methyl ester (a fullerene derivative, which may be abbreviated as PC₆₁BM).

In certain embodiments, where the electron-extraction layer 30 includes the extraction component layer 34, which is formed of TiO₂, the TiO₂ layer may be applied by depositing a TiO₂ precursor on the PD 10, such as tetrabutyl titanate (TBT), in solution, and then processing the TiO₂ precursor to form TiO₂, for example, by thermally annealing the TiO₂ precursor. A TiO₂ layer of any suitable thickness may be used.

In certain embodiments, where the electron-extraction layer 30 includes the passivating component layer 36 of PC₆₁BM, the PC₆₁BM layer may be applied by solution process such as solution casting. A PC₆₁BM layer of any suitable thickness may be used. In one or more embodiments, the PC₆₁BM layer may be from about 5 nm to about 400 nm in thickness, in other embodiments from about 10 nm to about 300 nm, and in still other embodiments from about 100 nm to 250 nm in thickness.

### Perovskite Light-Absorbing Active Layer

The perovskite light-absorbing active layer 40 is a layer capable of generating holes and electrons upon the absorption of light from any suitable light source. In one aspect, the structure of the perovskite material that is utilized by the light-absorbing layer 40 is denoted by the generalized formula AMX₃, where the A cation, the M atom is a metal cation, and X is an anion (O²⁻, C^{l-}, B^{r-}, I⁻, etc.). The metal cation M and the anion X form the MX₆ octahedra, where M is located at the center of the octahedral, and X lies in the corner around M. The MX₆ octahedra form an extended three-dimensional (3D) network of an all-corner-connected type.

Suitable the perovskite materials for using in light absorbing layer include organometal halide perovskite. In one or more embodiments, an organometal halide perovskite may be defined by the formula RMX₃, where the R organic cation, M is a metal cation, and each X is individual a halogen atom. In these or other embodiments, the perovskite light-absorbing active layer 40 includes organometal halide perovskite material, which may be defined by the formula CH₃NH₃PbI₃₋ₓ Clₓ, where x is from 0 to 3. Advantageously, CH₃NH₃PbI₃₋ₓ Clₓ is an inorganic/organic hybrid material that combines favorable properties of both inorganic and organic materials. In certain embodiments, the perovskite light-absorbing active layer 40 includes perovskite material that may be defined by the formula CH₃NH₃PbI₃.

In one or more embodiments, the perovskite light-absorbing active layer 40 may be applied to the photodetector 10 through a solution process. Although any suitable technique may be used, a suitable method of solution processing the perovskite light-absorbing active layer is a spin-coating process. After the perovskite light-absorbing active layer 40 is applied to the photodetector 10 thermal annealing may be applied to the photodetector 10. In certain embodiments, the perovskite light-absorbing active layer 40 is applied in a two-step process. In these or other embodiments, the perovskite light-absorbing layer 40 may be prepared by separately depositing an organohalide salt layer and a metal halide salt layer. The organohalide salt and a metal halide salt may be applied through a solution process such as depositing through spin coating. In one or more embodiments, the organohalide salt may be applied to the photodetector 10 first. In other embodiments, the metal halide salt may be applied to the photodetector 10 first. Suitable metal halide salts include, but are not limited to PbICl, PbI₂ or PbCl₂. Suitable organohalide salts include, but are not limited to, CH₃NH₃I or CH₃NH₃Cl.

The perovskite light-absorbing active layer 40 may have any suitable thickness. In one or more embodiments, the perovskite light-absorbing active layer 40 has a thickness of about 100 nm to about 1200 nm, in other embodiments, from abbot 400 nm to about 1000 m, and in other embodiments from about 600 nm to about 700 nm in thickness.

### Hole-Extraction Layer

The hole-extraction layer (HEL) 50 is a layer capable of capturing a hole generated in the perovskite light-absorbing active layer 40 and transferring it to the electrode 60. Exemplary materials for preparing the hole-extraction layer 50 include, but are not limited to, MoO₃, P3HT [poly(3-hexylthiophene-2,5-diyl)], and PEDOT:PSS [poly(3,4-ethylenedioxythiophene):poly(styrenesulfonate)]. As previously discussed, the hole-extraction layer 50 may include one or more sub-layers 54, 56 that are capable of capturing a hole generated in the perovskite light-absorbing layer 40. In one aspect the hole-extraction sub-layer 54 may include a layer of MoO₃, while the hole-extraction sub-layer 56 includes a layer of P3HT. In these or other embodiments, the layer 56 of P3HT may be disposed between the perovskite light-absorbing layer 40 and the MoO₃ layer 54.

In certain embodiments where the hole-extraction layer 50 includes the layer 54 of MoO₃, the MoO₃ may be applied to the photodetector 10 by thermal evaporation. In these or other embodiments, the MoO₃ layer may be from about 4 nm to about 400 nm, in other embodiments from about 6 nm to about 200 nm, and in other embodiments about 8 to about 50 nm in thickness.

In certain embodiments, where the hole-extraction layer 50 includes the layer 56 of poly(3-hexylthiophene-2,5-diyl), the poly(3-hexylthiophene-2,5-diyl) may be applied to the photodetector 10 by dispensing a solution of poly(3-hexylthiophene-2,5-diyl) to a spinning device. Exemplary conditions for depositing a solution of poly(3-hexylthiophene-2,5-diyl) include preparing a 20 mg/mL solution of poly(3-hexylthiophene-2,5-diyl) in dichlorobenzene (o-DCB) and depositing it onto a device spinning at 1000 RPMs for approximately 55 seconds. A poly(3-hexylthiophene-2,5-diyl) layer of any suitable thickness may be used.

In certain embodiments where the hole-extraction layer 50 comprises a layer of PEDOT:PSS [poly(3,4-ethylenedioxythiophene):poly(styrenesulfonate], the PEDOT:PSS may be applied to the photodetector 10 by casting the PEDOT:PSS from an aqueous solution. In these or other embodiments, the PEDOT:PSS may be from about 5 nm to about 200 nm, in other embodiments from about 10 to about 100 nm, and in other embodiments from about 20 to about 60 nm in thickness.

### Photodetector Properties

The photodetector 10 of the present invention has a desirable external quantum efficiency (EQE). In one or more embodiments, the photodetector 10 of the present invention has an EQE greater than 50%; in other embodiments, greater than 60%; in other embodiments, greater than 70%; in other embodiments, greater than 80%; and in still other embodiments, greater than 85%.

In addition, the photodetector 10 of the present invention has a desirable detectivity, which may be obtained from about 375 nm to about 800 nm. In one or more embodiments, the photodetector 10 has a detectivity greater than 2×10¹² Jones, in other embodiments, greater than 2.8×10¹² Jones, in other embodiments, greater than 3×10¹² Jones, and in still other embodiments, greater than 4×10¹² Jones.

### Solution-Processed Perovskite Photodetector I

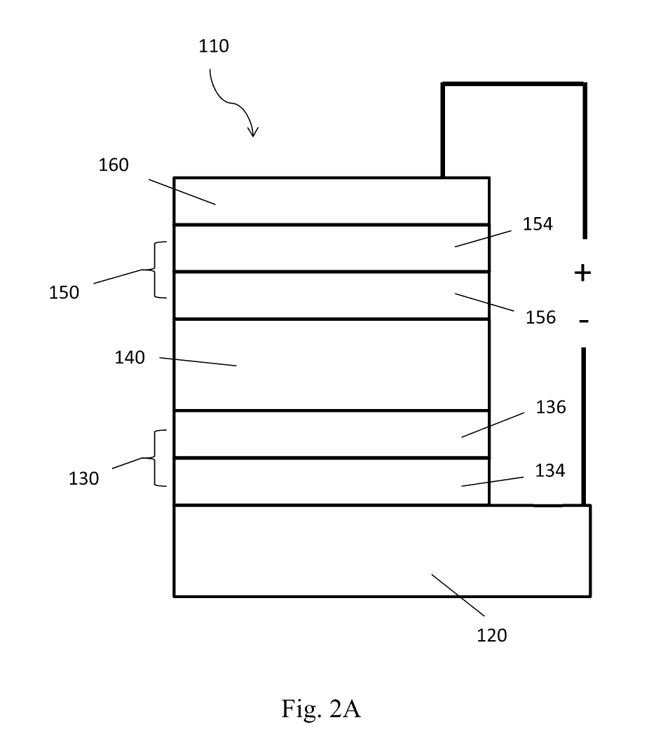

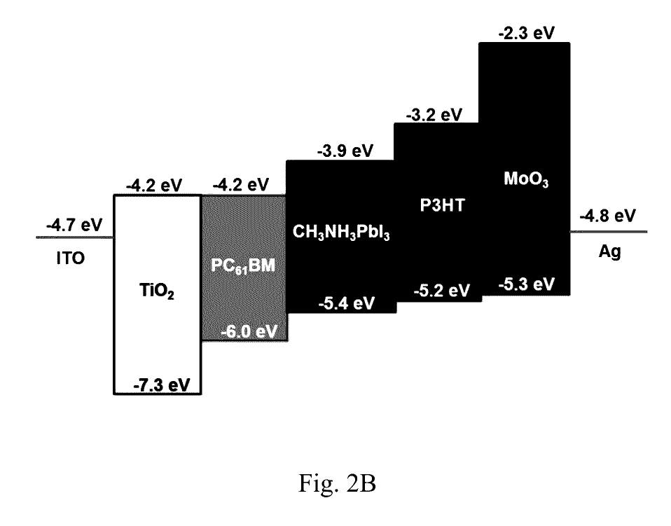

The following discussion presents the structural details of a particular embodiment of the photodetector 10, which is referred to by numeral 110, as shown in FIG. 2A. Specifically, the photodetector 110 is a solution-processed perovskite hybrid photodetector that is based on a conventional device structure of ITO/TiO₂ (or TiO₂/PC₆₁BM)/perovskite/P3HT/MoO₃/Ag. The photodetector 110 comprises a laminated or layered structure formed in a manner to be discussed. Photodetector 110 includes a transparent or partially-transparent electrically-conductive electrode 120 that is prepared from indium-tin-oxide (ITO), or any other suitable material. In one aspect, the electrically-conductive electrode 120 may be disposed upon a glass substrate (not shown). Positioned adjacent to the electrically-conductive electrode 120 is the electron-extraction layer (EEL) 130. The electron-extraction layer 130 includes an electron-extraction component layer 134 formed of TiO₂ and a passivating component layer 136 formed of PC₆₁BM. In certain embodiments, the photodetector 110 may not include the passivating component layer 136, thereby leaving only the electron-extraction component layer 134. Positioned adjacent to the electron-extraction layer 130 is a light-absorbing active layer 140, which is formed of perovskite material that is defined by the formula CH₃NH₃PbI Positioned adjacent to the perovskite active layer 140 is a hole-extraction layer (HEL) 150. The hole-extraction layer 150 includes a hole-extraction component layer 154 that is formed of P3HT [poly(3-hexylthiophene-2,5-diyl] and a hole-extraction component layer 156 formed of MoO₃. However, it should be appreciated that the HEL 150 may be formed of any suitable material. Positioned adjacent to the hole-extraction layer 150 is an electrically-conductive electrode 160 formed of any suitable high work-function metal, such as silver (Ag).

As such, the photodetector 110 of the present invention overcomes the problems of conventional photodetector designs by eliminating the strong acidic PEDOT:PSS layer, and by substituting the low work-function metal of aluminum (Al) with a high work-function metal electrode of silver (Ag), which can be printed from paste inks. Such a configuration of the photodetector 110 dramatically improves the stability of the PD 110, as well as its compatibility with large-scale, high-throughput manufacturing techniques, such as roll-to-roll manufacturing. When operated at room temperature, the detectivities (D*) of the solution-processed photodetector 110 is more than about 10¹² Jones for wavelengths from about 375 nm to 800 nm. The detectivities achieved by the photodetector 110 are further enhanced at least four times by modifying the surface of the TiO₂ component layer 134 of the electron extraction layer (EEL) 130 with the solution-processed PC₆₁BM component layer 136.

As previously discussed, the solution-processed photodetector 110 may be configured so that the electron-extraction layer (EEL) 130 comprises only the TiO₂ component layer 134, or may be configured to comprise both the TiO₂ component layer 134 and the component layer 136 formed of TiO₂/PC₆₁BM, which are fabricated on the ITO substrate 120. The lowest unoccupied molecular orbital (LUMO) and highest occupied molecular orbital (HOMO) energy levels of TiO₂, PC₆₁BM, CH₃NH₃PbI₃, P3HT, MoO₃ and work functions of the ITO and Ag electrodes of the PD 110 are shown in FIG. 2B. The LUMO energy levels of P3HT (−3.2 eV) and MoO₃ (−2.3 eV) which are higher than that of CH₃NH₃PbI₃ (−3.9 eV) indicates that separated electrons can be blocked by both P3HT and MoO₃ hole extraction layers (HEL). The similar values of HOMO energy levels of the HEL 150 and the CH₃NH₃PbI₃ (perovskite) indicates that separated holes can be efficiently transported through HEL 150 and collected by the Ag electrode (anode) 160. On the other hand, the HOMO energy levels of TiO₂ (−7.4 eV) and PC₆₁BM (−6.0 eV) which are lower than that of CH₃NH₃PbI₃ (−5.4 eV) (perovskite) indicates that separated holes can be blocked by both the TiO₂ and the PC₆₁BM of the electron-extraction layer (EEL) 130. Efficient electron extraction from the CH₃NH₃PbI₃ layer 140 to the PC₆₁BM/TiO₂ EEL 130 is facilitated due to the ˜0.3 eV energy offset between the LUMO energy levels of the PC₆₁BM/TiO₂ and CH₃NH₃PbI₃. Based on the band alignment, high photocurrent and low dark current are expected from PD 110.

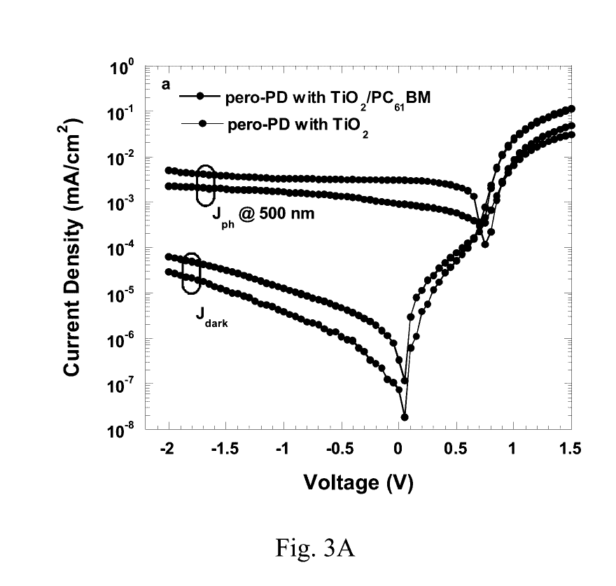

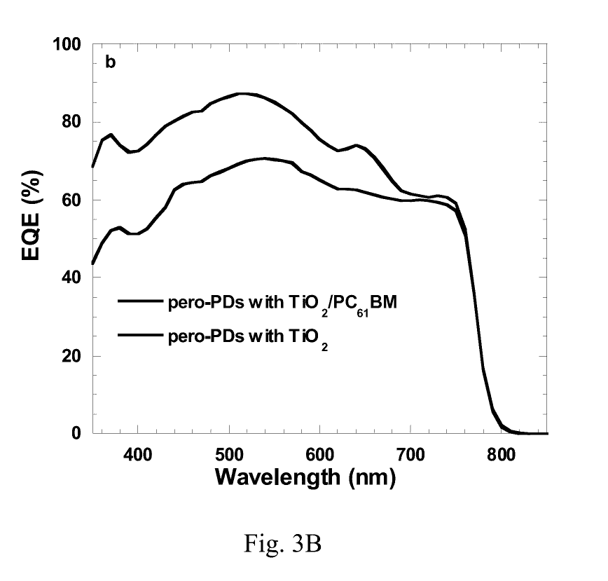

FIG. 3A presents the current density versus voltage (J-V) characteristics of the PD 110 with the TiO₂ EEL 130 and the TiO₂/PC₆₁BM EEL 130 when subjected to both dark conditions and when subjected to monochromatic light illumination at the wavelength (λ) of 500 nm, measured at room temperature. Under dark conditions, the reversed dark-current densities of the PD 110 with a TiO₂/PC₆₁BM EEL 130 are approximately 10 times smaller than the PD 110 with a TiO₂ EEL 130. The low dark-current densities suggest that the PD 110 with a TiO₂/PC₆₁BM EEL 130 possesses high detectivity. Under the illumination of monochromatic light at a wavelength (λ) of about 500 nm with an illumination intensity of about 0.53 mW/cm², large photocurrent densities are observed from the PD 110, which suggest that the PD 110 possesses desirable photodiode operation. Moreover, nearly two times larger photocurrent densities are observed from the PD 110 having a TiO₂/PC₆₁BM EEL 130, as compared with the PD 110 having a TiO₂ EEL 130. This demonstrates that PC₆₁BM is able to boost the charge carrier transport from the perovskite CH₃NH₃PbI₃ active layer 140 to the TiO₂ EEL 130, resulting in high photocurrent densities, which is consistent with the band alignment shown in FIG. 2B.

FIG. 3B shows the external quantum efficiencies (EQE) versus wavelength of the PD 110 measured under short-circuit conditions and under reverse bias using lock-in amplification techniques, measured at room temperature. At about λ=500 nm, the EQE values achieved were approximately 62% and 84% for the PD 110 with a TiO₂ EEL 130 and for the PD 110 with a TiO₂/PC₆₁BM EEL 130, respectively. The photoresponsivity of the PD 110 is calculated according to the following formula: photoresponsivity (R)=Jₚₕ/L_{light}, where Jₚₕ is the photocurrent and L_{light} is the incident light intensity. Thus, the photoresponsivity values achieved are 250 mA/W and 339 mA/W for the PD 110 with a TiO₂ EEL 130, and for the PD 110 with a TiO₂/PC₆₁BM EEL 130, respectively. These photoresponsivities (R) are much higher than those from conventional photodetectors.

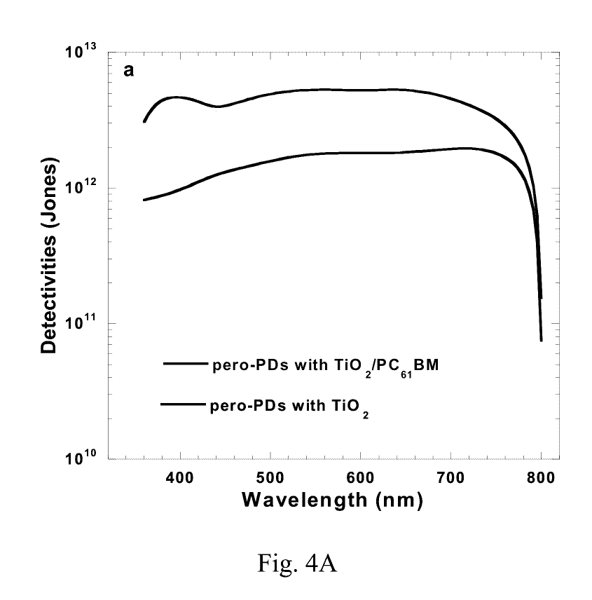

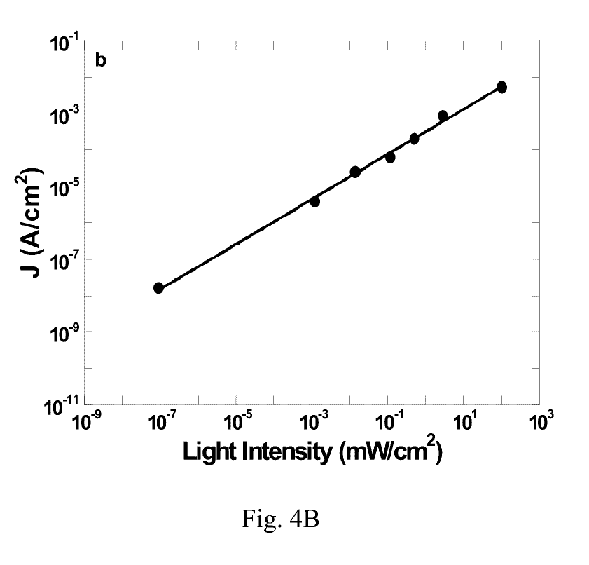

The detectivities (D*) of the photodetector 110 are expressed as D*=R/(2qJ_{d})^{1/2} (Jones, 1 Jones=1 cm·Hz^{1/2}/W), where q is the absolute value of electron charge (1.6×10⁻¹⁹ Coulombs), and J_{d} is the dark current density (A/cm²). Accordingly, the detectivities (D*) are calculated to be 1.4×10¹² Jones, and 4.8×10¹² Jones at about λ=500 nm, for the PD 110 with a TiO₂ EEL 130 and for the PD 110 with a TiO₂/PC₆₁BM EEL 130, respectively. Based on the EQE spectra of the PD 110, the D* versus wavelength are estimated, as shown in FIG. 4A. It is clear that the detectivities D* of the PD 110 with a TiO₂/PC₆₁BM EEL 130 are notably higher than the PD 110 that utilizes the TiO₂ EEL 130. This is the result of the combined function of PC₆₁BM of simultaneously accelerating the charge carrier transfer at the CH₃NH₃PbI₃/TiO₂ interface of the EEL 130 and decreasing the dark current densities.

Based on the photocurrent densities versus the incident light intensity of the photodetector 110, as shown in FIG. 4B, the linear dynamic range (LDR) or photosensitivity linearity (typically quoted in dB) is calculated according to the equation: LDR=20 log (J*ₚₕ/J_{dark}), where J*ₚₕ is the photocurrent measured at a light intensity of 1 mW/cm². The LDR is over approximately 100 dB for the PD 110 with a TiO₂/PC₆₁BM EEL 130. This large LDR is comparable to that of silicon (Si) photodetectors (120 dB) and is significantly higher than indium gallium arsenide (InGaAs) photodetectors (66 dB). All of these results demonstrate that the photodetector 110 of the present invention is comparable to conventional Si photodetectors and InGaAs photodetectors.

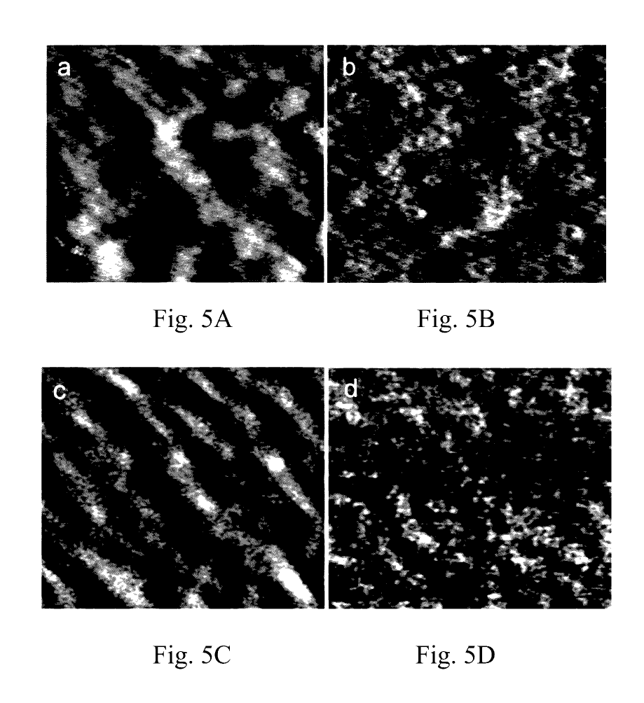

In order to evaluate the detectivities of photodetectors 110 with a TiO₂/PC₆₁BM EEL 130, atomic force microscopy (AFM) was used to study the surface morphologies of the TiO₂ thin film and TiO₂/PC₆₁BM thin film of the EEL 130. Specifically, height AFM images are shown in FIGS. 5A and 5B, while AMF phase images are shown in FIGS. 5C and 5D. Based on the images, the sol-gel processed TiO₂ thin film shows a rather uneven surface, with a relatively large root mean square roughness (RMS) of about 3.5 nm. Upon passivation of the TiO₂ with PC₆₁BM, the surface becomes substantially smoother, with a remarkably reduced RMS of 0.25 nm. The smooth surface of the TiO₂/PC₆₁BM EEL 130 produces fewer defects and traps in the interface between the perovskite (i.e. CH₃NH₃PbI₃) and the TiO₂/PC₆₁BM EEL 130, resulting in small reverse dark current densities. Such structural parameters of the PD 110 are in agreement with the J-V characteristics of the PD 110 shown in FIG. 3A, thus verifying the dark current densities were suppressed by the passivation of the inhomogeneous TiO₂ thin film by the PC₆₁BM layer.

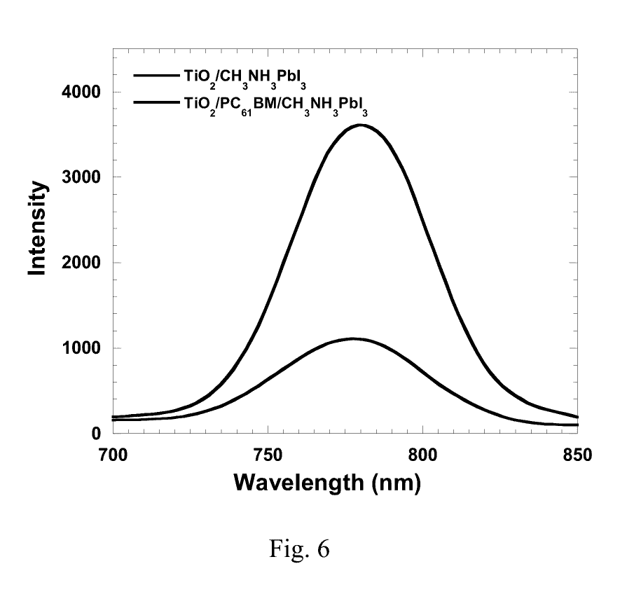

To confirm that the TiO₂ layer of the EEL 130 is passivated by the PC₆₁BM layer, a photoluminescence (PL) analysis was performed to inspect the charge carrier generation at the TiO₂/CH₃NH₃PbI₃ (i.e. perovskite) and the TiO₂/PC₆₁BM/CH₃NH₃PbI₃ interfaces. FIG. 6 shows the photoluminescence spectra of the TiO₂/CH₃NH₃PbI₃ and the TiO₂/PC₆₁BM/CH₃NH₃PbI₃ thin films used by the photodetector 110. Thus, it was found that a more strikingly quenching effect is observed in the TiO₂/PC₆₁BM/CH₃NH₃PbI₃ than in that of TiO₂/CH₃NH₃PbI₃. This indicates that a more efficient electron transport has occurred at the PC₆₁BM/CH₃NH₃PbI₃ (perovskite) interfaces over that of the TiO₂/CH₃NH₃PbI₃ (perovskite) interfaces, confirming the role of higher electrically conductive PC₆₁BM (˜10⁻⁷ S/cm) over the TiO₂ (˜10⁻¹¹ S/cm) for favoring the electron extraction at the EEL 130/CH₃NH₃PbI₃ 140 material interfaces, resulting in high photocurrents in the PD 110 with TiO₂/PC₆₁BM EEL 130.

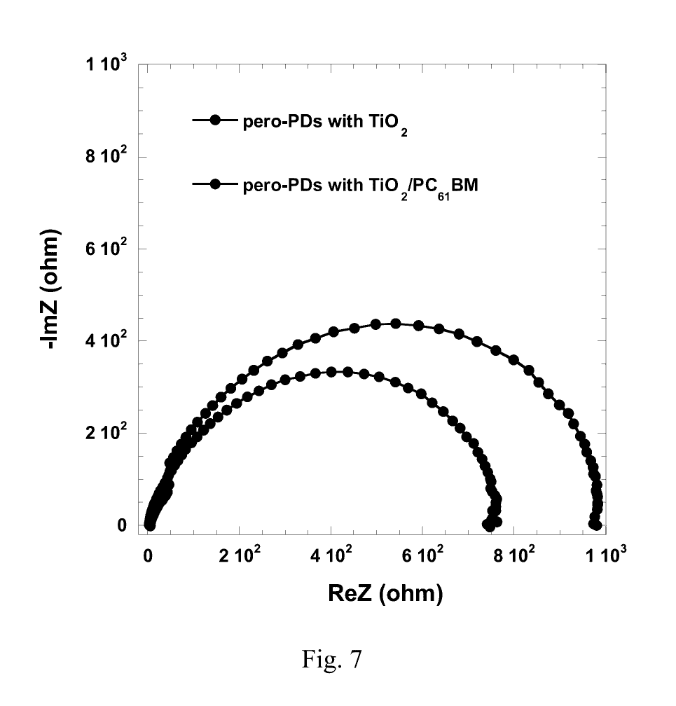

To further evaluate the charge carrier transport at the EEL 130/CH₃NH₃PbI₃ 140 interfaces, AC impedance spectroscopy (IS) was performed, which provides detailed electrical properties of the PD 110 that cannot be determined through direct current measurement. FIG. 7 presents the IS spectra of the PD 110 using either a TiO₂ or a TiO₂/PC₆₁BM EEL 130. The internal series resistance (R_{S}) is the sum of the sheet resistance (R_{SH}) of the electrodes and the charge-transfer resistance (R_{CT}) inside the perovskite thin film and at perovskite material/EEL (HEL) interfaces. Since all the PDs 110 possess the same device structure, the R_{SH} is assumed to be the same. The only difference is the R_{CT}, which arises from the different electron transport at the EEL/CH₃NH₃PbI₃ interface. Upon the modification with the PC₆₁BM layer, the R_{S} of the PD 110 significantly decreased from about 976Ω to about 750Ω, further confirming the role of PC₆₁BM in favoring the electron transfer from the CH₃NH₃PbI₃ to the cathode electrode 120.

In order to evaluate photodetector 110 of the present invention, the various components thereof were prepared in the manner discussed below. However, the following discussion should not be viewed as limiting the scope of the invention.

### Materials

The TiO₂ precursor, tetrabutyl titanate (TBT) and PC₆₁BM were purchased from Sigma-Aldrich and Nano-C Inc., respectively, and used as received without further purification. Lead iodine (PbI₂) was purchased from Alfa Aesar. Methylammonium iodide (CH₃NH₃I, MAI) was synthesized using the method reported in Z. Xiao, et al., Energy Environ. Sci. 2014, 7, 2619, which is incorporated herein by reference. The perovskite precursor solution was prepared, whereby the PbI₂ and the CH₃NH₃I were dissolved in dimethylformamide (DMF) and ethanol with a concentration of about 400 mg/mL for PbI₂, and about 35 mg/mL for CH₃NH₃I, respectively. All the solutions were heated at about 100° C. for approximately 10 minutes to make sure both the MAI and PbI₂ are fully dissolved.

### Thin Film Characterizations

Surface morphologies of TiO₂ and PC₆₁BM were measured by tapping-mode atomic force microscopy (AFM) imaging using a NanoScope NS3A system (Digital Instrument). Photoluminescence (PL) spectra were obtained with a 532 nm pulsed laser as excitation source at a frequency of 9.743 MHz.

### Pero-PDs Fabrication and Characterization

The compact TiO₂ layer was deposited on a pre-cleaned ITO substrate from tetrabutyl titanate (TBT) isoproponal solution (concentration 3 vol %) followed by thermal annealing at about 90° C. for approximately 60 min in an ambient atmosphere. Next, PC₆₁BM layer was casted on the top of the compact TiO₂ layer formed from dichlorobenzene (o-DCB) solution with a concentration of 20 mg/mL, at 1000 RPM for 35 seconds. For the PHJ (perovskite hybrid junction) PD (photodetector) fabrication, the PbI₂ layer was spin-coated from a 400 mg/mL DMF solution at 3000 RPM for about 35 seconds, on the top of the PC₆₁BM layer, then the film was dried at about 70° C. for approximately five minutes. After the film cooled to room temperature, MAI layer was spin-coated on the top of PbI₂ layer from a 35 mg/mL ethanol solution at 3000 RPM for about 35 seconds, followed by transferring to the hot plate (100° C.) immediately. After thermal annealing at 100° C. for about two hours, the poly(3-hexylthiophene-2,5-diyl) P3HT layer was deposited from a 20 mg/mL o-DCB solution at 1000 RPM for about 55 seconds. Lastly, the pero-HSCs (perovskite hybrid solar cells) were finished by thermally evaporating MoO₃ (8 nm) and aluminum (Ag) (100 nm). The device area is defined to be about 0.16 cm².

The current density-voltage (J-V) characteristics of the PD 110 were measured using a Keithley 2400 source-power unit. The PD were characterized using a solar simulator at a wavelength of about 500 nm with an irradiation intensity of approximately 2.61 mW/cm². The external quantum efficiency (EQE) was measured through the incident photon to charge carrier efficiency (IPCE) measurement setup in use at European Solar Test Installation (ESTI) for cells and mini-modules. A 300 W steady-state xenon lamp provides the source light. Up to 64 filters (8 to 20 nm width, range from 300 to 1200 nm) are available on four filter-wheels to produce the monochromatic input, which is chopped at 75 Hz, superimposed on the bias light and measured via the usual lock-in technique.

The impedance spectroscopy (IS) was obtained using a HP 4194A impedance/gain-phase analyzer, under the illumination of white light with the light intensity of about 100 mW/cm², with an oscillating voltage of 50 mV and frequency of 5 Hz to 13 MHz.

### Thin Film Characterizations

Surface morphologies of the TiO₂ and the PC₆₁BM were measured by tapping-mode atomic force microscopy (AFM) imaging using a NanoScope NS3A system (Digital Instrument). Photoluminescence (PL) spectra were obtained with a 532 nm pulsed laser as an excitation source at a frequency of about 9.743 MHz.

### Solution-Processed Perovskite Photodetector II

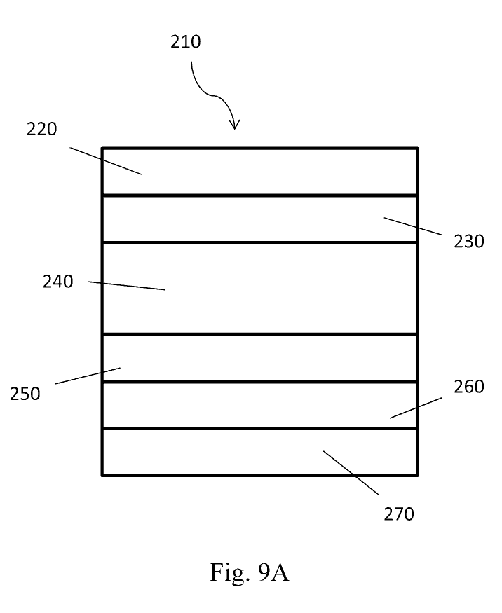

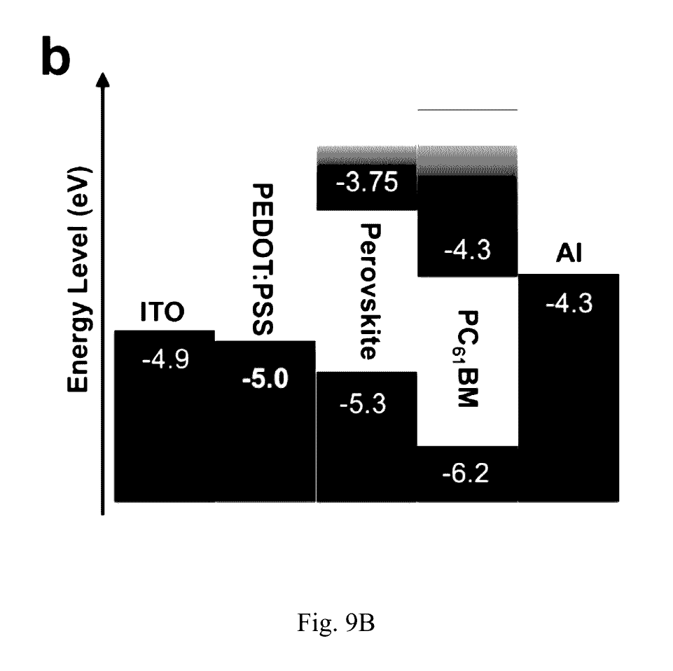

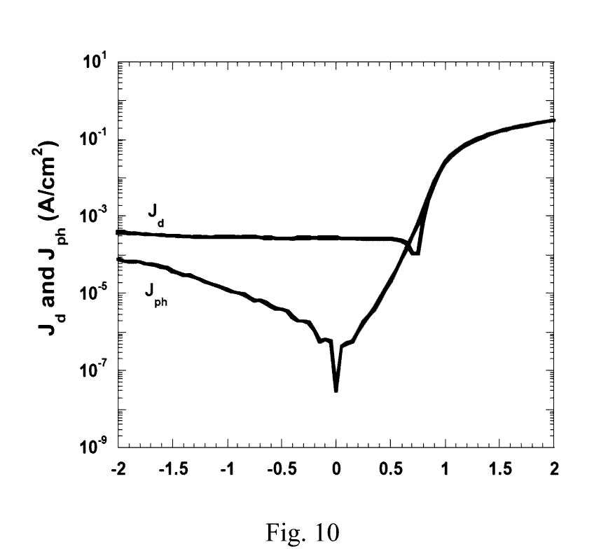

The following discussion presents the structural details of another embodiment of the PD 10 discussed above, which is referred to by numeral 210 shown in FIG. 9A. Specifically, the photodetector 210 comprises a laminated or layered structure formed in a manner to be discussed. Photodetector 210 includes a transparent or partially-transparent, electrically-conductive electrode 260 that is prepared from indium-tin-oxide (ITO) or another suitable material, and is disposed upon a suitable glass substrate 270. Positioned adjacent to the electrically-conductive electrode 260 is a hole-extraction layer (HEL) 250 formed of poly(3,4-ethylenedioxythiophene):poly(styrenesulfonate) (i.e. PEDOT:PSS). Positioned adjacent to the hole-extraction layer 250 is a light-absorbing active layer 240, which is formed of perovskite, which is defined by the formula CH₃NH₃PbI₃₋ₓ Clₓ, where x is from 0 to 3. Positioned adjacent to the perovskite active layer 240 is an electron-extraction layer (EEL) 230 formed of PC₆₁BM. Positioned adjacent to the electron-extraction layer 230 is an electrically-conductive electrode 220 formed of aluminum (Al).

In one aspect, the CH₃NH₃PbI₃₋ₓ Clₓ active layer 240 has a thickness of about 650 nm and is solution-processed upon an about 40 nm thick poly(3,4-ethylenedioxythiophene):poly(styrenesulfonate) (i.e. PEDOT:PSS) layer 250. The electron extraction layer 230 of phenyl-C61-butyric methyl ester (PC61BM) has a thickness of about 200 nm and is followed by thermal deposition of an about 100 nm aluminum (Al) electrode layer 220. FIG. 9B depicts the energy level diagram of CH₃NH₃PbI₃₋ₓ Clₓ, PC61BM and workfunctions of PEDOT:PSS and aluminum that comprise the photodetector 210. The LUMO offset between the CH₃NH₃PbI₃₋ₓ Clₓ and the PC61BM is much larger than 0.3 eV, indicating the charge transfer between CH₃NH₃PbI₃₋ₓ Clₓ and PC61BM is efficient. Furthermore, both the anode and cathode electrodes 260, 220 are small enough to ensure an efficient photo-induced charge transfer from the BHS active layer 240 to the respective electrodes 220, 260. In addition, the surface roughness of the perovskite active layer 240 is large enough to form a planar heterojunction with the PC61BM layer 230, making good contact for electron transfer.

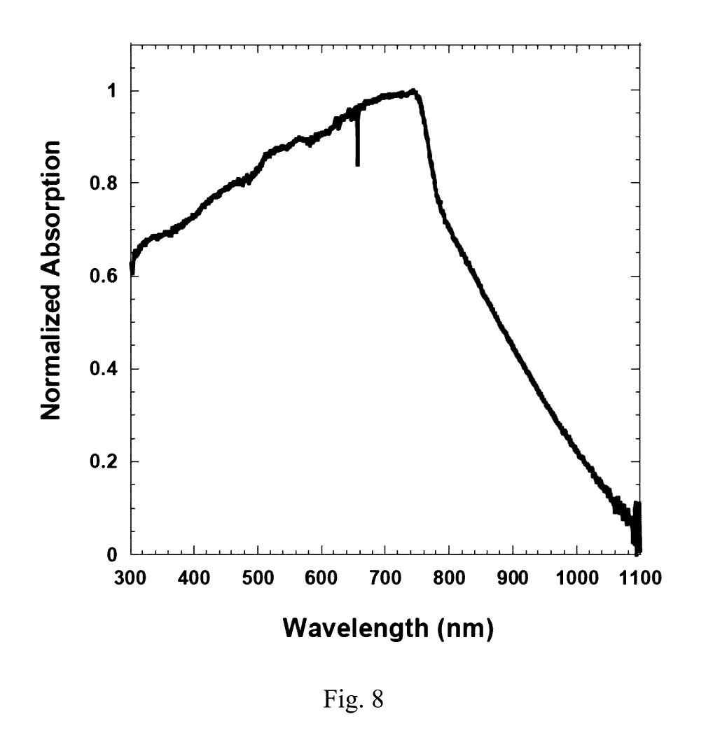

FIG. 8 shows the UV-vis absorption spectra of the CH₃NH₃PbI₃₋ₓClₓ utilized by the photodetector 210. The light extinction coefficient is 3.4×10⁻³ at about 780 nm. Moreover, by tuning the composition of the CH₃NH₃PbI₃₋ₓ Clₓ perovskite material, the absorption spectra can be extended to the near-infrared region.

FIG. 10 displays the J-V characteristics of the PD 210 that is measured under dark conditions and under illuminated conditions. In the dark, the PD 210 shows a rectification ratio of about 10³, demonstrating good photodiode properties and operation. Under illumination of about 1.23 mW/cm² at approximately λ=500 nm, the reverse current was largely enhanced by photo-generated charge carriers, while the forward current remained almost the same. Jₚₕ was demonstrated to be orders of magnitude higher than J_{d} at the reversed bias, which implies an efficient exciton dissociation and ultrafast photo-induced charge transfer in the CH₃NH₃PbI₃₋ₓ Clₓ/PC61BM bilayer. However, smaller J_{d} may be achieved by interfacial engineering of the PD 210 or modification of the interfaces between perovskite/PC61BM and metal/perovskite of the photodetector 210.

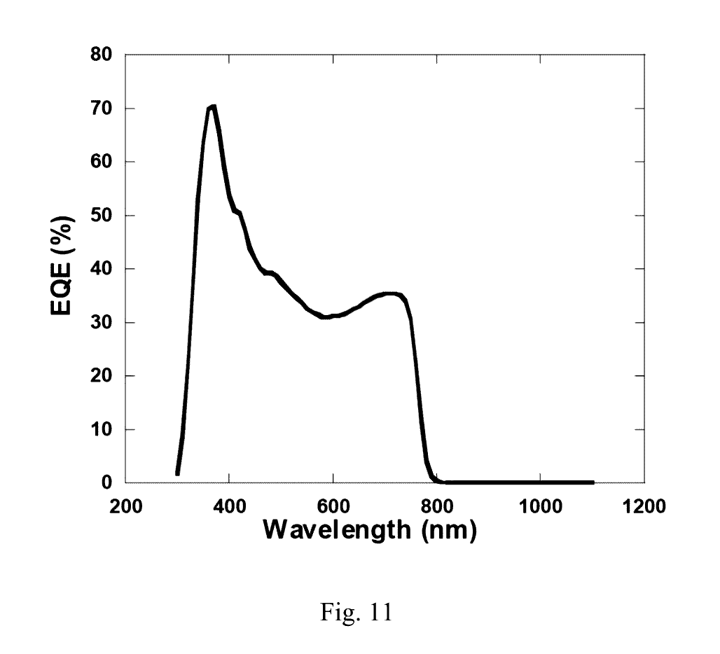

The spectra response of the photodetector 210 was measured under short-circuit condition using lock-in amplifier, and presented in FIG. 11. This data indicates that photons absorbed in the visible to NIR range by the CH₃NH₃PbI₃₋ₓ Clₓ perovskite do contribute to the photocurrent. At about λ=500 nm, the EQE is approximately 66% electron-per-photon, and the corresponding responsivity (R) is calculated to be about 264 mA/W, which is significantly larger than the values reported before.

D* is one of the most important figures of merits (FOM) for evaluating performance of a photodetector, and is expressed as D*=(Jₚₕ*/L_{light})/(2qJ_{d})^{1/2}, where Light is the incident light intensity and q is the electron charge. D* is calculated to be 2.85×10¹² Jones at λ=500 nm with light intensity of 1.23 mW/cm², shown in table 1 for the photodetector 210.

TABLE 1
Parameters for perovskite-based PD 210.

| Jd (A/cm²) | Jph (A/cm²) | EQE (%) | R (mA/W) | D* (Jones) |
|---|---|---|---|---|
| 2.69 × 10⁻⁸ | 3.24 × 10⁻⁴ | 66 | 264 | 2.85 × 10¹² |

As such, the high-charge carrier mobility, large light-extinction coefficient and large film thickness of the perovskite material makes it an excellent light absorber in the photodetector 10, 110, and 210 of the present invention. Additionally, the solution-processed perovskite photodetectors of the present invention exhibit a wide and strong response ranging from UV (ultraviolet) to the NIR (near infrared), with a high detectivity (D*) of 2.85×10¹² Jones at wavelength of about 500 nm and an enhanced device stability.

Therefore, one advantage of the photodetector of the present invention is that the photodetector uses low-cost perovskite as an active layer to reduce the overall cost of the photodetector. Still another advantage of the photodetector of the present invention is that it is solution processable. Another advantage of the photodetector of the present invention is that it is able to be operated at room temperatures with desirable operating performance. Yet another advantage of the photodetector of the present invention is that it is compatible with large-scale manufacturing techniques.

Thus, it can be seen that the objects of the present invention have been satisfied by the structure and its method for use presented above. While in accordance with the Patent Statutes, only the best mode and preferred embodiments have been presented and described in detail, with it being understood that the present invention is not limited thereto or thereby. Accordingly, for an appreciation of the true scope and breadth of the invention, reference should be made to the following claims.

1. A photodetector comprising:
a first electrode;
an electron-extraction layer disposed on the first electrode;
a perovskite active layer disposed on the electron-extraction layer;
a hole-extraction layer disposed on the perovskite active layer; and
a second electrode;
wherein at least one of the first or second electrodes is at least partially transparent to light, wherein the photodetector includes a first hole-extraction layer and a second hole-extraction layer.

2. The photodetector of claim 1, wherein the perovskite active layer comprises organometal halide perovskite.

3. The photodetector of claim 2, wherein the organometal halide is defined by the formula CH₃NH₃PbI₃₋ₓ Clₓ, where x is from 0 to 3.

4. The photodetector of claim 3, wherein the organometal halide is defined by the formula CH₃NH₃PbI₃.

5. The photodetector of claim 4, wherein the electron-extraction layer comprises TiO₂.

6. The photodetector of claim 3, wherein the TiO₂ is passivated by [6,6]-phenyl-C61-butyric acid methyl ester.

7. (canceled)

8. The photodetector of claim 1, wherein the first hole-extraction layer comprises MoO₃ and the second hole-extraction layer comprises poly(3-hexylthiophene-2,5-diyl).

9. The photodetector of claim 3, wherein the electron-extraction layer comprises [6,6]-phenyl-C61-butyric acid methyl ester.

10. The photodetector of claim 3, wherein the hole-extraction layer comprises poly(3,4-ethylenedioxythiophene):poly(styrenesulfonate).

11. The photodetector of claim 1, wherein the external quantum efficiency is greater than 50%.

12. A photodetector comprising:
a first electrode;
an electron-extraction layer disposed on the first electrode;
a perovskite active layer disposed on the electron-extraction layer;
a hole-extraction layer disposed on the perovskite active layer; and
a second electrode;
wherein at least one of the first or second electrodes is at least partially transparent to light, wherein detectivities greater than 2.8×10¹² Jones can be obtained for at least one wavelength between 375 nm to 800 nm.

13. The photodetector of claim 12, wherein the detectivities greater than 2.8×10¹² Jones can be obtained for the wavelengths between 375 nm to 800 nm.

14. A method of preparing a photodetector comprising:
providing a first electrode that is at least partially transparent to light;
disposing an electron-extraction layer on the first electrode;
disposing a perovskite light absorbing layer on the electron-extraction layer;
disposing a hole-extraction layer on the perovskite light-absorbing layer; and
disposing a second electrode on the hole-extraction layer, wherein the hole-extraction layer includes a layer comprising poly(3-hexylthiophene-2,5-diyl) and a layer comprising MoO₃.

15. The method of claim 15, wherein the step of disposing the perovskite light absorbing is performed by first disposing a layer comprising a metal halide salt on the electron-extraction layer and then disposing an organohalide salt on the layer comprising a metal halide salt.

16. The method of claim 15, wherein the metal halide salt layer is PbICl, PbI₂ or PbCl₂.

17. The method of claim 15, wherein the organohalide salt layer is CH₃NH₃I or CH₃NH₃Cl.

18. The method of claim 14, wherein the electron-extraction layer comprises TiO₂.

19. The method of claim 14, wherein the electron-extraction layer comprises TiO₂ formed by depositing a TiO₂ precursor and then processing the TiO₂ precursor to form TiO₂.

20. The method of claim 18, wherein the TiO₂ is passivated by depositing a layer comprising phenyl-C61-butyric acid methyl ester on the TiO₂.

21. The method of claim 14, wherein the hole-extraction layer comprises a material selected from MoO₃, poly(3-hexylthiophene-2,5-diyl), poly(3,4-ethylenedioxythiophene):poly(styrenesulfonate), and combinations thereof.

22. (canceled)

23. A method of preparing a photodetector comprising:
providing a first electrode that is at least partially transparent to light;
disposing a hole-extraction layer on the first electrode;
disposing a perovskite light absorbing layer on the hole-extraction layer;
disposing an electron-extraction layered on the perovskite light absorbing layer; and
disposing a second electrode on the electron-extraction layer,
wherein the hole-extraction layer includes a layer comprising Poly(3-hexylthiophene-2,5-diyl) and a layer comprising MoO₃.

24. The method of claim 23, wherein the step of disposing the perovskite light-absorbing layer is performed by first disposing a layer comprising a metal halide salt on the hole-extraction layer and then disposing an organohalide salt on the layer comprising a metal halide salt.

25. The method of claim 24, wherein the metal halide salt layer is PbICl, PbI₂ or PbCl₂.

26. The method of claim 24, wherein the organohalide salt is CH₃NH₃I or CH₃NH₃Cl.

27. The method of claim 23, wherein the electron-extraction layer comprises TiO₂.

28. The method of claim 23, wherein the electron-extraction layer comprises TiO₂ formed by depositing a TiO₂ precursor and then processing the TiO₂ precursor to form TiO₂.

29. The method of claim 27, wherein the TiO₂ is passivated by depositing a layer comprising phenyl-C61-butyric acid methyl ester on the TiO₂.

30. The method of claim 23, wherein the hole-extraction layer comprises a material selected from MoO₃, poly(3-hexylthiophene-2,5-diyl), poly(3,4-ethylenedioxythiophene):poly(styrenesulfonate), and combinations thereof.

31. (canceled)
